(19) United States
(12) Patent Application Publication
(10) Pub. No.: US 2025/0376783 A1
(43) Pub. Date: Dec. 11, 2025

(54) SINGLE-CRYSTAL CATHODE MATERIAL AND PREPARING METHOD THEREOF

(71) Applicants: GUIZHOU ZHENHUA E-CHEM INC., Guiyang (CN); Guizhou Zhenhua E-CHEM Co., Ltd., Guiyang (CN); Guizhou Zhenhua Yilong E-CHEM Co., Ltd, Guizhou (CN)

(72) Inventors: Jin HUANG, Guiyang (CN); Lijuan WANG, Guiyang (CN); Ye YU, Guiyang (CN); Lu LI, Guiyang (CN); Chaoyi ZHOU, Guiyang (CN)

(21) Appl. No.: 19/031,953

(22) Filed: Jan. 18, 2025

(30) Foreign Application Priority Data
Jun. 11, 2024 (CN) 202410741623.8

(51) Int. Cl. C30B 1/02; C30B 29/26; H01M 4/02; H01M 4/131

(52) U.S. Cl. CPC C30B 1/02; C30B 29/26; H01M 4/131; H01M 2004/021; H01M 2004/028

(57) ABSTRACT

A single-crystal cathode material and preparing method thereof are provided. The method involves mixing and ball milling a lithium source with a nickel-cobalt-manganese precursor and then performing a first sintering treatment to obtain the first main material. The first sintering temperature is 650 to 950° C. and sintering time is 15 to 30 hours. The first main material is then mixed and ball-milled with source A and performing a second sintering treatment to prepare the single-crystal cathode material. The second sintering temperature is 650-950° C. and sintering time is 5-15 hours. A precursor is used to directly prepare a single-crystal cathode material without jet milling.

### TECHNICAL FIELD

The present disclosure relates to single-crystal cathode material and preparing method thereof, belonging to field of lithium-ion battery technology.

### BACKGROUND

With the vigorous development of the global electric vehicle and battery market, lithium-ion batteries have become main battery technology route in the field of new energy vehicles and energy storage, and the business of lithium-ion battery cathode materials is an important part of the lithium battery industry chain. In the early days, the lithium battery cathode material was mainly polycrystalline. With the rapid development of the new energy industry, fast charging and high voltage have become market demands, and single-crystal cathode materials have become the main technical route.

Single-crystal cathode materials have no grain boundaries inside, which makes them less likely to grain boundary cracking and secondary particle breakage during the charging and discharging process, thereby improving the cycle stability of the battery. Since single-crystal materials reduce grain boundaries, they reduce side reactions with the electrolyte, which helps to improve the safety and life span of the battery. Moreover, single-crystal materials can increase the packing density, thereby increasing the energy density of the battery.

In the prior art, amorphous precursor sintering methods and jet milling methods are generally used to prepare single-crystal cathode materials. Among them, the amorphous precursor sintering methods have high requirements for the precursor, which needs to control the crystal structure of the precursor through co-precipitation methods. It is not only a complex method with high costs, but also causes uneven ion precipitation during the precipitation process, leading to lower battery performance. The jet milling method is to grind the sintered cathode material by gas flow collision to obtain single-crystal cathode materials. However, the jet milling method produces fine powders, and it is necessary to separate the fine powders with a cyclone, which increases the production cost.

### SUMMARY

In view of the shortcomings in the existing technology, this invention proposes a single-crystal cathode material and preparing method thereof, which uses a polycrystalline precursor to prepare single-crystal cathode material without the need for the jet milling, greatly improving the compatibility of the process.

The technical solution of this invention: a preparing method for making a single-crystal cathode material, wherein the method comprising:
Step 1, mixing and ball milling a lithium source with a nickel-cobalt-manganese polycrystalline precursor and then performing a first sinter-treating to obtain a first main material, wherein sinter temperature is 650 to 950° C. and sinter time is 15-30 hours;
Step 2, mixing and ball milling the first main material with source A and then performing a second sinter-treating to prepare a single-crystal cathode material, wherein sinter temperature is 650-950° C. and sinter time is 5-15 hours.

In the above method, mass ratio of the first main material to the source A is 1.0: (0.002-0.01).

At same time, the present application further provides a single-crystal cathode material prepared by the above preparing method, and the chemical formula is LiₐNiₓCo_{y}Mn₂O₂·cA, wherein 1≤a≤1.2, 0<c≤0.05, 0≤x≤1, 0≤y≤0.5, 0≤z≤0.5, and x+y+z=1, and the source A is a coating and selected from oxides or carbonates with large ionic radius.

Further, the oxides or carbonates with large ionic radius are one or more oxides or carbonates of Nb, Sr W and W.

Further, an average particle size of the single-crystal cathode material is 2-6 μm.

Further, specific surface area of the single-crystal cathode material is 0.5-1.5 m²/g.

Further, total free lithium in the single-crystal cathode material is less than 1500 ppm by mass.

The present application further provided a cathode plate, comprising a cathode current collector and cathode active substance, wherein the cathode active substance comprises the above single-crystal cathode materials.

The present application further provides a battery, comprising the above cathode plate.

The present application further provides an electrical device, wherein the electrical device includes the above battery and the battery is used to provide electrical energy.

Due to the above technical solution, the advantages of the present invention is as follows: the invention uses a polycrystalline precursor to directly make single-crystal cathode materials, and the synthesis of single-crystal cathode materials is achieved without the need for jet milling, making the process simple and cost-effective, and greatly enhancing the compatibility of the process.

### BRIEF DESCRIPTION OF THE DRAWINGS

FIG. 1 shows a SEM image of the precursor of the present invention.

FIG. 2 shows a SEM image of the first main material of the present invention.

FIG. 3 shows a SEM image of the single-crystal cathode material prepared by the method or the present invention.

### DETAILED DESCRIPTION OF EMBODIMENTS

For a better understanding of the technical solutions according to the embodiments of the present invention, further explanation and description will be provided below in conjunction with some preferred embodiments of the present application.

In this specification, quantities, ratios, and other numerical values are sometimes presented in a range format. It should be understood that such a range format is used for convenience and brevity, and should be flexibly understood, not only including the numerical values explicitly specified as the range limits, but also including all individual values or sub-ranges covered within the range herein, as if each value and sub-range were explicitly specified.

The chemical formula of the single-crystal cathode material of the present application is LiₐNiₓCo_{y}Mn₂O₂·cA, wherein 1≤a≤1.2, 0<c≤0.05, 0≤x≤1, 0≤y≤0.5, 0≤z≤0.5, and x+y+z=1, and the source A is a coating source selected from one or more oxides or carbonates with large ionic radius. The oxides or carbonates with large ionic radius is one or more oxides or carbonates of Nb, Sr and W.

The single-crystal cathode material of the present application can be prepared using a conventional polycrystalline precursor without the jet milling method, greatly improving the compatibility of the process.

Compared with amorphous precursors, polycrystalline precursors have a higher yield, simpler process, and therefore relatively lower cost. Moreover, the process of this invention does not require jet milling, reducing the fine powders and eliminating the need for cyclone separation of fine powders, greatly optimizing the synthesis process of the single-crystal cathode material.

The coating source A is used for shallow coating. Due to its relatively large ionic radius, it tends to accumulate on the surface of primary particles, reducing the adhesion between particles. Under high temperature, it leads to the dispersion of primary particles, forming single-crystal cathode materials.

According to some embodiments, specific surface area of the above single-crystal cathode material can be 0.5-1.5 m²/g, and the average particle size is 2-6 μm. the above single-crystal cathode material contains less than 1500 ppm of total free lithium by mass.

According to some embodiments of the present application, the above single-crystal cathode material can be used as a cathode material for lithium-ion batteries. For example, the above single-crystal cathode material, conductive carbon black (S.P), and binder polyvinylidene fluoride (PVDF) are added to N-methylpyrrolidonc (NMP) (the weight ratio of the compound to NMP is 2.1:1) in a weight ratio of 94:3:3, and are fully mixed, stirred to form a uniform slurry to prepare the cathode material (or cathode active material), coated on an aluminum foil current collector, dried, and pressed to obtain a cathode plate, which can constitute an electrode assembly with the anode plate.

The present application further provides a battery, in particular to a lithium-ion battery, which comprises the above electrode assembly. This lithium-ion battery can be used in digital products, electric vehicles, or energy storage fields.

For example, a lithium-ion secondary battery is usually composed of electrode assembly, non-aqueous electrolyte, separator, and casing. In particular, the electrode assembly can include a cathode plate and an anode plate. As described above, the cathode plate comprises a cathode current collector and the cathode active material coated on the cathode current collector, as well as conventional binders, conventional conductive aids, and other materials. The cathode active material can comprise the above compound of the present application. The anode is made from a current collector and a conventional anode active material coated on the current collector, as well as conventional binders, conventional conductive aids, and other materials. The separator is a PP/PE film commonly used in this industry, and it is used to separate the cathode from the anode. The casing is the container for the cathode, anode, separator, and electrolyte.

When a 1 mol/L lithium hexafluorophosphate solution is used as the electrolyte, the solvent in the lithium hexafluorophosphate solution is a mixed solvent of dimethyl carbonate (DMC), ethylene carbonate (EC), and diethyl carbonate (DEC) in a mass ratio of 1:1:1, and when a mixture of artificial graphite, conductive carbon black, carboxymethyl cellulose, and binder in a weight ratio of 95:1:1:3 is used as anode material, the cathode plate is prepared with a mixture of the above compound, conductive carbon black, and PVDF in a weight ratio of 94:3:3, and then the battery cell is prepared, with the model number 454261, to ultimately form a battery.

The present application further provides an electrical device, including the above battery, wherein the battery is used to provide power. The electrical device can include digital products, electric vehicles, energy storage devices, etc. For example, it can be used for portable electronic devices and electric vehicles, and can also be used for energy storage power systems such as hydropower, thermal power, wind power, and solar power stations.

The present application provides a method for making single-crystal cathode material, comprising:
Step 1, mixing and ball milling a lithium source with a nickel-cobalt-manganese polycrystalline precursor and then performing a first sinter-treating to obtain a first main material, wherein sinter temperature is 650 to 950° C. and sinter time is 15-30 hours;
Step 2, mixing and ball milling the first main material with source A and then performing a second sinter-treating to prepare a single-crystal cathode material, wherein the sinter temperature is 650-950° C. and the sinter time is 5-15 hours.

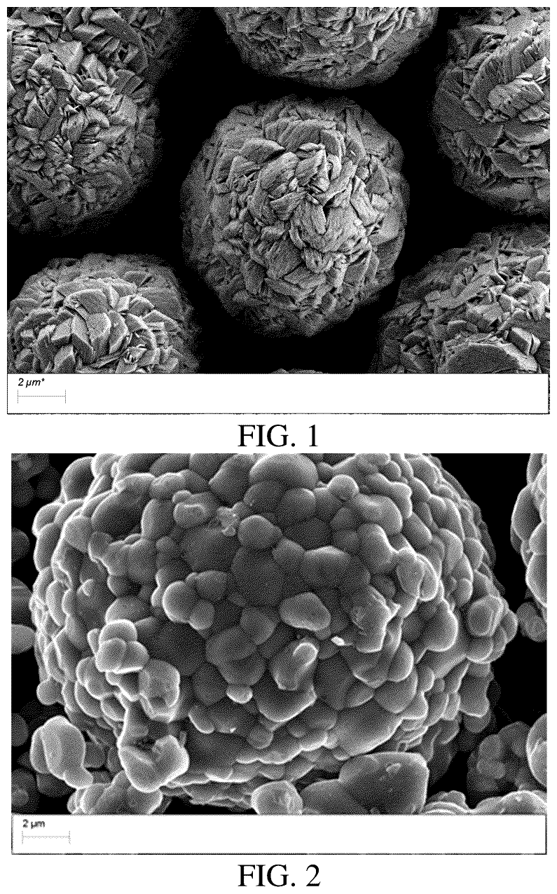

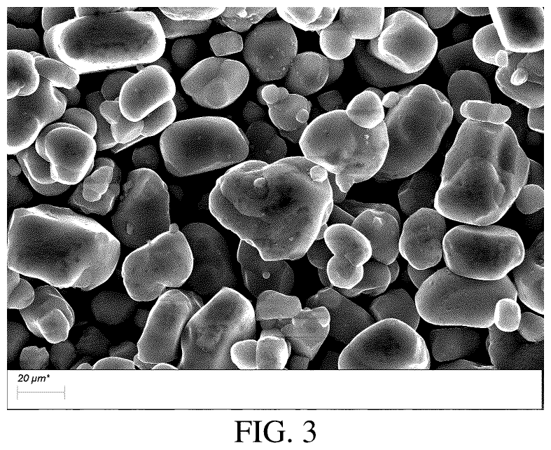

The morphology of the precursor is shown in FIG. 1, which is a flaky structure composed of fine needle-like combinations. After mixing with the lithium source, the blocky structure of the cathode material formed by high-temperature sintering is shown in FIG. 2. During this process, there is a process of fine needle-like structures merging and growing into a primary blocky structure. If the source A is added in Step 1, during sintering, it will penetrate into the crystal interior during the process of fine needle-like structures merging and growing into blocky structures, that is, it will enter the crystal structure interior during the crystal mergence and growth process, and will not be enriched on the surface of the primary blocky structure. When the source A is mixed and sintered in Step 2, due to the limitation of the crystal material channels, the large ionic radius of the A source cannot penetrate into the crystal interior and can only be enriched on the surface of the primary blocky structure, resulting in reduced adhesion between particles, the dispersion of primary particles, and the formation of single-crystal cathode materials. Conversely, if source A is added in Step 1, this effect will not be formed.

Compared with existing technologies, the preparing methods of the single-crystal cathode material provided by embodiments of the present application use a polycrystalline precursor and can synthesize single-crystal cathode materials without jet milling.

According to some embodiments of the present application, the lithium source can be selected from lithium hydroxide monohydrate or lithium carbonate.

According to some embodiments of the present application, the nickel-cobalt-manganese polycrystalline precursor is a hydroxide containing nickel, cobalt, and manganese elements, with a particle size of 8 μm-20 μm.

According to some embodiments of the present application, the mass ratio of the first main material to source A is 1.0: (0.002-0.01), for example, 1: (0.003-0.007).

According to some embodiments of the present application, in the above methods, the first sintering temperature is 650-950° C., for example, 700-900° C., the first sintering time is 15-30 hours, for example, 20-24 hours, the second sintering temperature is 650-950° C., for example, 700-900° C., and the second sintering time is 5-15 hours, for example, 6-12 hours.

According to some embodiments of the present application, in the above methods, the first sintering temperature is 930° C., 900° C., 850° C., 780° C., or 720° C., and the first sintering time is 18 hours, 24 hours, or about 26 hours. The second sintering temperature is 900° C., 850° C., 820° C., 780° C., or 680° C., and the second sintering time is 6 hours, 8 hours, 12 hours, or 14 hours.

The following specific implementation examples illustrate the compound and preparing method and application thereof proposed according to the present application, and the reagents or instruments not recorded in this application text are content that can be conventionally confirmed by ordinary technicians in the field.

The reagents used in the following examples are shown in Table 1-1.

TABLE 1-1
Information on the reagents used in the examples herein

| Reagent Name | Grade | Model | Manufacturer |
|---|---|---|---|
| Nickel-Cobalt-Manganese | Ni:Co:Mn = | Particle size: 10 μm, | Guangdong Jana |
| Precursor | 1/3:1/3:1/3 | Chemical formula: | Energy Technology |
| | | Ni_{1/3}Co_{1/3}Mn_{1/3} (OH)₂ | Co., Ltd |
| Nickel-Cobalt-Manganese | Ni:Co:Mn = | Particle size: 10 μm, | Guangdong Jana |
| Precursor | 50:20:30 | Chemical formula: | Energy Technology |
| | | Ni_{0.5}Co_{0.2}Mn_{0.3} (OH)₂ | Co., Ltd |
| Nickel-Cobalt-Manganese | Ni:Co:Mn = | Particle size: 10 μm, | Guangdong Jana |
| Precursor | 60:10:30 | Chemical formula: | Energy Technology |
| | | Ni_{0.6}Co_{0.1}Mn_{0.3} (OH)₂ | Co., Ltd |
| Nickel-Cobalt-Manganese | Ni:Co:Mn = | Particle size: 10 μm, | Guangdong Jana |
| Precursor | 7:1:2 | Chemical formula: | Energy Technology |
| | | Ni_{0.7}Co_{0.1}Mn_{0.2} (OH)₂ | Co., Ltd |
| Nickel-Cobalt-Manganese | Ni:Co:Mn = | Particle size: 10 μm, | Guangdong Jana |
| Precursor | 83:07:10 | Chemical formula: | Energy Technology |
| | | Ni_{0.83}Co_{0.07}Mn_{0.10} (OH)₂ | Co., Ltd |
| Nickel-Cobalt-Manganese | Ni:Co:Mn = | Particle size: 10 μm, | Guangdong Jana |
| Precursor | 92:5:3 | Chemical formula: | Energy Technology |
| | | Ni_{0.92}Co_{0.05}Mn_{0.03} (OH)₂ | Co., Ltd |
| Nickel-Cobalt-Manganese | Ni:Co:Mn = | Particle size: 10 μm, | Guangdong Jana |
| Precursor | 97:2:1 | Chemical formula: | Energy Technology |
| | | Ni_{0.97}Co_{0.02}Mn_{0.01} (OH)₂ | Co., Ltd |
| Nano niobium oxide | Ceramic | — | Anhui Xuancheng |
| | Grade | | Jingrui New Material |
| | | | Co., Ltd. |
| Nano tantalum oxide | Ceramic | — | Anhui Xuancheng |
| | Grade | | Jingrui New Material |
| | | | Co., Ltd. |
| Nano molybdenum oxide | Ceramic | — | Anhui Xuancheng |
| | Grade | | Jingrui New Material |
| | | | Co., Ltd. |
| Nano tungsten oxide | Ceramic | — | Anhui Xuancheng |
| | Grade | | Jingrui New Material |
| | | | Co., Ltd. |
| Lithium hydroxide | Battery | 99.5 wt % | Jiangxi Ganfeng |
| monohydrate | Grade | | Lithium Co., Ltd. |
| Lithium Carbonate | Battery | 99.5 wt % | Jiangxi Ganfeng |
| | Grade | | Lithium Co., Ltd |
| Methyl Red | Chemical | 99.5 wt % | Tianjin Guangfu |
| | Pure | | Technology |
| | | | Development Co., |
| | | | Ltd. |
| Phenolphthalein | Chemical | 99.9 wt % | Chengdu Jinshan |
| | Pure | | Chemical Reagent |
| | | | Co., Ltd. |
| HCL | Chemical | 99.9 wt % | Sichuan Xiluong |
| | Pure | | Science Co., Ltd. |
| High Purity Oxygen | Industrial | Purity99.95% | Shenzhen Nanshan |
| | Grade | | Gas Station |
| Conductive carbon black | Battery | Super P Li | Schunk Carbon |
| | Grade | | Technology AG, |
| | | | Switzerland |
| N-Methyl-2-Pyrrolidone | Battery | 99.5% content | Jiangsu Nanjing |
| | Grade | | Jinlong Chemical |
| | | | Factory |
| Polyvinylidene Fluoride | Battery | Solef 6020 | Solvay Chemicals, |
| | Grade | | USA |
| Aluminum Foil | Battery | Thickness 16 μm | Alcoa Inc., USA |
| | Grade | | |
| Electronic Tape | Electronic | Green, Width 10 mm | 3M Company, USA |
| | Grade | | |
| Lithium Foil | Electronic | DiameterΦ20 mm, | Shanghai Shunyou |
| | Grade | Purity ≥99.9% | Metal Material Co., |
| | | | Ltd. |
| Electrolyte | Electronic | Mixture solvent: | Shenzhen Xinzebon |
| | Grade | Dimethyl Carbonate | Company |
| | | (DMC):Ethylene | |
| | | Carbonate (EC):Diethyl | |
| | | Carbonate (DEC) = | |
| | | 1:1:1 (mass ratio), | |
| | | Electrolyte:Lithium | |
| | | Hexafluorophosphate; | |
| | | Concentration of | |
| | | Lithium | |
| | | Hexafluorophosphate | |
| | | in the electrolyte is 1 | |
| | | mol/L | |
| Separator | — | PP/PE/PP three-layer | Celgard, LLC, USA |
| | | material, Celgard | |
| | | M825, Thickness | |
| | | 16 μm | |
| Aluminum Plastic Film | Industrial | Total Thickness 160 μm | Dai Nippon Printing |
| | Grade | | Co., Ltd. (DNP), |
| | | | Japan |

The equipment and analytical methods used in the following examples are as follows:

The mixing and ball milling equipment is the SHQM model dual planetary ball mill from Lianyungang Chunlong Experimental Instrument Co., Ltd.

The present application uses a fully automatic specific surface area and porosity analyzer (TriStar II 3020 from Micromeritics Instrument Corp., USA) to test and analyze the specific surface area.

The test method for free lithium in the compound is as follows:

Accurately weigh an appropriate amount of the sample in m grams (about 30 g), accurate to 0.01 g; put the sample into a 250 ml conical flask, place a magnetic stirring bar, and add 100 mL of deionized water; place the conical flask on a magnetic stirrer and stir for 30 minutes; filter the mixture through filter paper and a funnel; use a 50 mL pipette to transfer 50 mL of the filtrate into a 100 ml beaker, and stir using a magnetic stirring bar; place the beaker on a magnetic stirrer, and add 2 drops of phenolphthalein indicator; titrate with a 0.05 mol/L hydrochloric acid standard titration solution until the solution changes from red to colorless; record the volume V1 (end point 1) of the 0.05 mol/L hydrochloric acid standard titration solution; add 2 drops of methyl red indicator and the color changes from colorless to yellow; titrate with a 0.05 mol/L hydrochloric acid standard titration solution until the solution changes from yellow to orange; heat the beaker on a hot plate until the solution boils (the color changes from orange to yellow); remove the 100 mL beaker and cool down to room temperature; place the beaker on a magnetic stirrer again; titrate with a 0.05 mol/L hydrochloric acid standard titration solution until the color changes from yellow to light red and record the volume V2 (end point 2); Lithium hydroxide:

$$\begin{matrix}LiOH ( wt \% ) = [ V 2 - 2 \times ( V 8 - V 1 ) ] \times 0.05 \times 23.946 \times 2 \times 100 / ( m \times 1000 ) ; Lithium carbonate : \\ {Li}_{2} {CO}_{3} ( wt \% ) = ( V 2 - V 1 ) \times 0.05 \times 73.886 \times 2 \times 100 / ( m \times 1000 ) ; \\ Free lithium : Li + ( wt \% ) = V 2 \times 0.05 \times 6.94 \times 2 \times 100 / ( m \times 1000 ) .\end{matrix}$$

The test for average particle size: The MS3000 laser particle size analyzer is used for testing, the method is as follows:

Take an appropriate amount of the sample into a 100 mL beaker, firstly rinse around the inner wall of the beaker with a wash bottle, then rinse the sample stuck at the bottom of the beaker with a wash bottle, and control the amount of pure water added to the beaker to 20-30 mL, wherein ultrasonic time is 5 min (stir for 10 s before, during, and after ultrasonication, and stirring speed is about 2r/s). Add 100±10 mL of pure water to the sampler of the MS3000 laser particle size analyzer, adjust the speed to 3000 r/min, click start, the instrument automatically aligns, measure the background and wait for the prompt to operate. After ultrasonication, transfer the sample to the stirring trough, and rinse the beaker with a wash bottle to ensure all the sample is transferred. After the sample is completely added, the software automatically starts measuring. After the measurement is completed, the data is automatically saved.

The preparing method for making the battery (the battery cell model is 454261) using the compound of the present application is as follows:

Cathode plate preparation: add the compound proposed by the present application, conductive carbon black (S.P), binder polyvinylidene fluoride (PVDF) in a weight ratio of 94:3:3 into N-methylpyrrolidone (NMP) (the weight ratio of the compound herein to NMP is 2.1:1) for thorough mixing, and stir to form a uniform slurry, coat on an aluminum foil current collector, dry and press into a cathode plate.

Anode plate preparation: add the anode artificial graphite, conductive carbon black (S.P), carboxymethyl cellulose (CMC), and binder (SBR) in a weight ratio of 95:1:1:3 into sufficient pure water, stir to form uniform slurry, coat it on a copper foil current collector, dry and press to form an anode plate.

The separator is a PP/PE/PP three-layer composite film material.

Spot weld the pressed cathode and anode plate with ears, insert the separator, roll on a winding machine, and then put it into a soft package fixture for top and side sealing, then put it into an oven for baking. After that, inject 9 g of electrolyte in an environment with a relative humidity of less than 1.5%, after 48 hours of formation (Zhejiang Hangke LIP-3AHB06 high-temperature formation system), and vacuum seal it.

Sample drying and high-temperature battery testing use Dongguan Coreay Machinery KPBAK-03E-02 high-efficiency vacuum drying oven.

The charge and discharge test of the lithium-ion secondary battery of the present application is carried out according to the test method of GB/T18287-2000, tested on Wuhan Blue Electric Battery Tester (Wuhan Blue Electric CT2001C test equipment). Due to different battery systems, the impact on the cycle retention rate of materials is large. The battery system used in the experiment is the most common evaluation system, that is, a solution of 1 mol/L lithium hexafluorophosphate is used as the electrolyte, the solvent in the lithium hexafluorophosphate solution is a mixed solvent of dimethyl carbonate (DMC):ethylene carbonate (EC):diethyl carbonate (DEC)=1:1:1 (mass ratio), and the anode material is a mixture of artificial graphite, conductive carbon black, carboxymethyl cellulose, and binder in a weight ratio of 95:1:1:3. The battery cell model is 454261, so as to expose the actual defects of the cathode material as soon as possible and determine the performance of the cathode material.

### Example 1

Add lithium hydroxide monohydrate and a precursor with a molar ratio of Ni:Co:Mn=1/3:1/3:1/3 (the chemical formula: Ni_{1/3}Co_{1/3}Mn_{1/3} (OH)₂), in a molar ratio of Li:(Ni+Co+Mn)=1.08:1 and ball mill at a rotation speed of 40 Hz for 10 minutes to ensure uniform mixing, then the material (i.e., the mixed material) is discharged. The mixed material is placed in a muffle furnace, sintered for 18 hours at 930° C. under an oxygen atmosphere with a heating rate of 5° C./min, and cooled down to room temperature. After that, it is ball milled for another 10 minutes at a rotation speed of 40 Hz to obtain the first main material. Then, according to the mass ratio of the first main material to tungsten oxide of 1.0:0.004, the appropriate amount of tungsten oxide is weighed and added to the first main material for ball milling at a rotation speed of 40 Hz for 10 minutes. The uniformly mixed material is placed in a muffle furnace, sintered at 900° C. under an oxygen atmosphere with a heating rate of 10° C./min for 8 hours, cooled down to room temperature, and ball-milled for another 10 minutes at a rotation speed of 40 Hz. The material is then sieved using a 300-mesh metal screen to obtain the single-crystal cathode material 1.

The particle size, specific surface area, free lithium content, and battery testing of the single-crystal cathode material 1 are conducted, and the data can be found in Table 1.

### Example 2

Add lithium hydroxide monohydrate and a precursor with a molar ratio of Ni:Co:Mn=5:2:3 (the chemical formula: Ni_{0.5}Co_{0.2}Mn_{0.3} (OH)₂), in a molar ratio of Li:(Ni+Co+Mn)=1.06:1 and ball mill at a rotation speed of 40 Hz for 10 minutes to ensure uniform mixing, then the material (i.e., the mixed material) is discharged. The mixed material is placed in a muffle furnace, sintered for 24 hours at 900° C. under an oxygen atmosphere with a heating rate of 5° C./min, and cooled down to room temperature. After that, it is ball milled for another 10 minutes at a rotation speed of 40 Hz to obtain the first main material. Then, according to the mass ratio of the first main material to niobium oxide of 1.0:0.005, the appropriate amount of niobium oxide is weighed and added to the first main material for ball milling at a rotation speed of 40 Hz for 10 minutes. The uniformly mixed material is placed in a muffle furnace, sintered at 900° C. under an oxygen atmosphere with a heating rate of 10° C./min for 6 hours, cooled down to room temperature, and ball-milled for another 10 minutes at a rotation speed of 40 Hz. The material is then sieved using a 300-mesh metal screen to obtain the single-crystal cathode material 2.

The particle size, specific surface area, free lithium content, and battery testing of the single-crystal cathode material 2 are conducted, and the data can be found in Table 1.

### Example 3

Add lithium hydroxide monohydrate and a precursor with a molar ratio of Ni:Co:Mn=6:1:3 (the chemical formula: Ni_{0.6}Co_{0.1}Mn_{0.3} (OH)₂), in a molar ratio of Li:(Ni+Co+Mn)=1.10:1 and ball mill at a rotation speed of 40 Hz for 10 minutes to ensure uniform mixing, then the material (i.e., the mixed material) is discharged. The mixed material is placed in a muffle furnace, sintered for 24 hours at 900° C. under an oxygen atmosphere with a heating rate of 5° C./min, and cooled down to room temperature. After that, it is ball-milled for another 10 minutes at a rotation speed of 40 Hz to obtain the first main material. Then, according to the mass ratio of the first main material to tungsten oxide of 1.0:0.006, the appropriate amount of tungsten oxide is weighed and added to the first main material for ball milling at a rotation speed of 40 Hz for 10 minutes. The uniformly mixed material is placed in a muffle furnace, sintered at 850° C. under an oxygen atmosphere with a heating rate of 10° C./min for 12 hours, cooled down to room temperature, and ball milled for another 10 minutes at a rotation speed of 40 Hz. The material is then sieved using a 300-mesh metal screen to obtain the single-crystal cathode material 3.

The particle size, specific surface area, free lithium content, and battery testing of the single-crystal cathode material 3 are conducted, and the data can be found in Table 1.

### Example 4

Add lithium hydroxide monohydrate and a precursor with a molar ratio of Ni:Co:Mn=7:1:2 (the chemical formula: Ni_{0.7}Co_{0.1}Mn_{0.2} (OH)₂), in a molar ratio of Li:(Ni+Co+Mn)=1.12:1 and ball mill at a rotation speed of 40 Hz for 10 minutes to ensure uniform mixing, then the material is discharged (i.e., the mixed material is obtained). The mixed material is placed in a muffle furnace, sintered for 24 hours at 850° C. under an oxygen atmosphere with a heating rate of 5° C./min, and cooled down to room temperature. After that, it is ball-milled for another 10 minutes at a rotation speed of 40 Hz to obtain the first main material. Then, according to the mass ratio of the first main material to strontium carbonate of 1.0:0.004, the appropriate amount of strontium carbonate is weighed and added to the first main material for ball milling at a rotation speed of 40 Hz for 10 minutes. The uniformly mixed material is placed in a muffle furnace, sintered at 820° C. under an oxygen atmosphere with a heating rate of 10° C./min for 14 hours, cooled down to room temperature, and ball-milled for another 10 minutes at a rotation speed of 40 Hz. The material is then sieved using a 300-mesh metal screen to obtain the single-crystal cathode material 4.

The particle size, specific surface area, free lithium content, and battery testing of the single-crystal cathode material 4 are conducted, and the data can be found in Table 1.

### Example 5

Add lithium hydroxide monohydrate and a precursor with a molar ratio of Ni:Co:Mn=83:07:10 (the chemical formula: Ni_{0.83}Co_{0.07}Mn_{0.10} (OH)₂), in a molar ratio of Li:(Ni+Co+Mn)=1.08:1 and ball mill at a rotation speed of 40 Hz for 10 minutes to ensure uniform mixing, then the material (i.e., the mixed material is obtained) is discharged. The mixed material is placed in a muffle furnace, sintered for 26 hours at 780° C. under an oxygen atmosphere with a heating rate of 5° C./min, and cooled down to room temperature. After that, it is ball-milled for another 10 minutes at a rotation speed of 40 Hz to obtain the first main material. Then, according to the mass ratio of the first main material to tungsten oxide of 1.0:0.006, the appropriate amount of tungsten oxide is weighed and added to the first main material for ball-milling at a rotation speed of 40 Hz for 10 minutes. The uniformly mixed material is placed in a muffle furnace, sintered at 780° C. under an oxygen atmosphere with a heating rate of 10° C./min for 8 hours, cooled down to room temperature, and ball-milled for another 10 minutes at a rotation speed of 40 Hz. The material is then sieved using a 300-mesh metal screen to obtain the single-crystal cathode material 5.

The particle size, specific surface area, free lithium content, and battery testing of the single-crystal cathode material 5 are conducted, and the data can be found in Table 1.

### Example 6

Add lithium hydroxide monohydrate and a precursor with a molar ratio of Ni:Co:Mn=92:05:03 (the chemical formula: Ni_{0.92}Co_{0.05}Mn_{0.03} (OH)₂), in a molar ratio of Li:(Ni+Co+Mn)=1.16:1 and ball mill at a rotation speed of 40 Hz for 10 minutes to ensure uniform mixing, then the material (i.e., the mixed material) is discharged. The mixed material is placed in a muffle furnace, sintered for 24 hours at 720° C. under an oxygen atmosphere with a heating rate of 5° C./min, and cooled down to room temperature. After that, it is ball-milled for another 10 minutes at a rotation speed of 40 Hz to obtain the first main material. Then, according to the mass ratio of the first main material to tungsten oxide of 1.0:0.004, the appropriate amount of tungsten oxide is weighed and added to the first main material for ball-milling at a rotation speed of 40 Hz for 10 minutes. The uniformly mixed material is placed in a muffle furnace, sintered at 680° C. under an oxygen atmosphere with a heating rate of 10° C./min for 8 hours, cooled down to room temperature, and ball-milled for another 10 minutes at a rotation speed of 40 Hz. The material is then sieved using a 300-mesh metal screen to obtain the single-crystal cathode material 6.

The particle size, specific surface area, free lithium content, and battery testing of the single-crystal cathode material 6 are conducted, and the data can be found in Table 1.

### Example 7

Add lithium hydroxide monohydrate and a precursor with a molar ratio of Ni:Co:Mn=97:02:01 (the chemical formula: Ni_{0.97}Co_{0.02}Mn_{0.01} (OH)₂), in a molar ratio of Li:(Ni+Co+Mn)=1.08:1 and ball mill at a rotation speed of 40 Hz for 10 minutes to ensure uniform mixing, then the material (i.e., the mixed material) is discharged. The mixed material is placed in a muffle furnace, sintered for 30 hours at 650° C. under an oxygen atmosphere with a heating rate of 5° C./min, and cooled down to room temperature. After that, it is ball-milled for another 10 minutes at a rotation speed of 40 Hz to obtain the first main material. Then, according to the mass ratio of the first main material to tungsten oxide of 1.0:0.004, the appropriate amount of tungsten oxide is weighed and added to the first main material for ball-milling at a rotation speed of 40 Hz for 10 minutes. The uniformly mixed material is placed in a muffle furnace, sintered at 650° C. under an oxygen atmosphere with a heating rate of 10° C./min for 15 hours, cooled down to room temperature, and ball-milled for another 10 minutes at a rotation speed of 40 Hz. The material is then sieved using a 300-mesh metal screen to obtain the single-crystal cathode material 7.

The particle size, specific surface area, free lithium content, and battery testing of the single-crystal cathode material 7 are conducted, and the data can be found in Table 1.

### Example 8

Add lithium hydroxide monohydrate and a precursor with a molar ratio of Ni:Co:Mn=1/3:1/3:1/3 (the chemical formula: Ni_{1/3}Co_{1/3}Mn_{1/3} (OH)₂), in a molar ratio of Li:(Ni+Co+Mn)=1.06:1 and ball mill at a rotation speed of 40 Hz for 10 minutes to ensure uniform mixing, then the material (i.e., the mixed material) is discharged. The mixed material is placed in a muffle furnace, sintered for 15 hours at 950° C. under an oxygen atmosphere with a heating rate of 5° C./min, and cooled down to room temperature. After that, it is ball-milled for another 10 minutes at a rotation speed of 40 Hz to obtain the first main material. Then, according to the mass ratio of the first main material to tungsten oxide of 1.0:0.004, the appropriate amount of tungsten oxide is weighed and added to the first main material for ball-milling at a rotation speed of 40 Hz for 10 minutes. The uniformly mixed material is placed in a muffle furnace, sintered at 950° C. under an oxygen atmosphere with a heating rate of 10° C./min for 5 hours, cooled down to room temperature, and ball-milled for another 10 minutes at a rotation speed of 40 Hz. The material is then sieved using a 300-mesh metal screen to obtain the single-crystal cathode material 8.

The particle size, specific surface area, free lithium content, and battery testing of the single-crystal cathode material 8 are conducted, and the data can be found in Table 1.

### Comparative Example 1

Add lithium hydroxide monohydrate and an amorphous precursor with a molar ratio of Ni:Co:Mn=83:07:10, in a molar ratio of Li:(Ni+Co+Mn)=1.12:1 and ball mill at a rotation speed of 40 Hz for 10 minutes to ensure uniform mixing, then the material (i.e., the mixed material) is discharged. The mixed material is placed in a muffle furnace, sintered for 20 hours at 800° C. under an oxygen atmosphere with a heating rate of 5° C./min, and cooled down to room temperature. The mixed material is then sieved using a 300-mesh metal screen to obtain the comparative single-crystal cathode material D1.

The particle size, specific surface area, free lithium content, and battery testing of the comparative single-crystal cathode material D1 are conducted, and the data can be found in Table 1.

### Comparative Example 2

Add lithium hydroxide monohydrate and a precursor with a molar ratio of Ni:Co:Mn=83:07:10 (the chemical formula: Ni_{0.83}Co_{0.07}Mn_{0.1} (OH)₂), in a molar ratio of Li:(Ni+Co+Mn)=1.10:1 and ball mill at a rotation speed of 40 Hz for 10 minutes to ensure uniform mixing, then the material (i.e., the mixed material) is discharged. The mixed material is placed in a muffle furnace, sintered for 28 hours at 830° C. under an oxygen atmosphere with a heating rate of 5° C./min, and cooled down to room temperature. The mixed material is jet milled and then sieved using a 300-mesh metal screen to obtain the comparative single-crystal cathode material D2.

The particle size, specific surface area, free lithium content, and battery testing of the comparative single-crystal cathode material D2 are conducted, and the data can be found in Table 1.

TABLE 1
Characterization Data of Compounds Obtained from Examples

| | | | Free | | Capacity |
|---|---|---|---|---|---|
| Single- | Specific | Particle | Lithium | Capacity | Retention |
| crystal | Surface | Size | Total Free | 4.2 V | (%) |
| cathode | Area | D50 | Lithium | 1 C | 4.3 V 45° |
| material | (m²/g) | (μm) | (ppm) | (mAh/g) | C.@300times |
| 1 | 0.54 | 4.25 | 140 | 148 | 97 |
| 2 | 0.65 | 3.78 | 220 | 158 | 97 |
| 3 | 0.68 | 4.16 | 320 | 163 | 95 |
| 4 | 0.74 | 3.88 | 580 | 175 | 93 |
| 5 | 0.82 | 3.29 | 780 | 191 | 90 |
| 6 | 0.97 | 3.43 | 970 | 195 | 84 |
| 7 | 1.02 | 3.34 | 1025 | 197 | 83 |
| 8 | 0.52 | 4.36 | 129 | 147 | 97 |
| D1 | 0.95 | 2.98 | 1210 | 188 | 89 |
| D2 | 1.12 | 2.78 | 1432 | 185 | 78 |

As shown in Table 1, the single-crystal cathode material made according to the examples described above has a total free lithium content of less than 1500 ppm, a specific surface area between 0.5 and 1.5 m²/g, and a particle size between 2.0 and 6.0 μm, a single-crystal morphology of primary particles.

From Table 1, it can be observed that in the examples implemented, the method of the present application can achieve the synthesis of single-crystal cathode materials. Compared to the two current methods for synthesizing single-crystal cathode materials, the present application is not dependent on the precursor. Any precursor can achieve single crystal, and there is no need for jet milling. This effectively avoids the damage to primary particles caused by air flow, thereby enhancing the stability of the material.

1. A direct tensile and acoustic testing machine under rock seepage, comprising a sample and a support frame,
wherein a top of the support frame is fixed with a top plate, a bearing plate is provided above the top plate, the bearing plate is provided with a plurality of vertical force transferring rods, the plurality of vertical force transferring rods vertically penetrate through the top plate and are in a sliding fit with the top plate and are affixed to a tensile base, a top of the tensile base is provided with a lower clamp holder, a bottom of the top plate is provided with an upper clamp holder, and a clamp center of the upper clamp holder overlaps with a clamp center of the lower clamp holder;
an upper channel is provided inside the upper clamp holder, one end of the upper channel is communicated with the outside, the other end is provided with an acoustic transmitting probe, and a transmitting direction of the acoustic transmitting probe is downward; and
a lower channel is provided inside the lower clamp holder, one end of the lower channel is communicated with the outside, the other end is provided with an acoustic receiving probe, and the acoustic receiving probe is configured to receive an acoustic wave from the acoustic transmitting probe;
an upper end of the sample is affixed to the upper clamp holder, an upper end face of the sample is provided with a seepage outflow hole, a seepage outflow channel is provided inside the upper clamp holder, one end of the seepage outflow channel is connected with the seepage outflow hole, and the other end is communicated with the outside;
a lower end of the sample is affixed to the lower clamp holder, a lower end face of the sample is provided with a seepage inflow hole, a seepage entry channel is provided inside the lower clamp holder, and one end of the seepage entry channel is connected with the seepage inflow hole, and the other end is communicated with the outside, and
wherein an upper horn-shaped sealing sleeve is provided between the acoustic transmitting probe and an inner wall of the upper channel, and a lower horn-shaped sealing sleeve is provided between the acoustic receiving probe and an inner wall of the lower channel.

2. (canceled)

3. The direct tensile and acoustic testing machine under rock seepage according to claim 1, wherein a first probe spring is provided below the acoustic receiving probe, and a second probe spring is provided above the acoustic transmitting probe.

4. The direct tensile and acoustic testing machine under rock seepage according to claim 1, wherein an outflow end packer is arranged inside the seepage outflow hole, and an outflow end packer sealing ring is provided between the outflow end packer and a side wall of the seepage outflow hole; and an inflow end packer is provided inside the seepage inflow hole, and an inflow end packer sealing ring is provided between the inflow end packer and a side wall of the seepage inflow hole.

5. The direct tensile and acoustic testing machine under rock seepage according to claim 1, wherein the seepage outflow channel is communicated with the outside through a seepage outflow end joint; and the seepage entry channel is communicated with the outside through a seepage inflow end joint.

6. The direct tensile and acoustic testing machine under rock seepage according to claim 1, wherein the support frame comprises a base and a plurality of columns, each column having a first end affixed to the base a second end affixed to the top plate by a first fixing nut.

7. The direct tensile and acoustic testing machine under rock seepage according to claim 1, wherein the tensile base is provided with a lower ball head sliding fitted with the tensile base, and the lower clamp holder is affixed to the lower ball head; and the top plate is provided with an upper ball head sliding fitted with the top plate, and the upper clamp holder is affixed to the upper ball head.

8. The direct tensile and acoustic testing machine under rock seepage according to claim 7, wherein the lower clamp holder is installed on the lower ball head through a lower latch, and the upper clamp holder is installed on the upper ball head through an upper latch.

9. The direct tensile and acoustic testing machine under rock seepage according to claim 1, wherein a lower end of each force transferring rods is affixed to the tensile by a second fixing nut.

10. A test method of the direct tensile and acoustic testing machine under rock seepage according to claim 1, comprising:
gluing a first end of the sample to the lower clamp holder and a second end of the sample to the upper clamp holder;
affixing an oil pressure protection heat shrink film on an outer wall of the lower clamp holder, the sample and the upper clamp holder; placing the rock tensile testing device in a pressure chamber; connecting the seepage outflow channel with a seepage outflow tube; connecting the seepage entry channel with the seepage inflow tube; passing a gas flow at an elevated pressure through the seepage inflow tube to produce seepage;
connecting the acoustic transmitting probe to an acoustic transmitting wire, and the acoustic receiving probe to an acoustic receiving wire, wherein the acoustic transmitting wire and the acoustic receiving wire are connected to an acoustic control system; and
carrying out an acoustic detection on the sample;
wherein the pressure chamber is filled with oil to apply a triaxial lateral compression stress, a compression load is applied to the bearing plate through an indenter of the testing machine, the compression load is transmitted through the plurality of force transferring rods to the tensile base, and the tensile base forms a tensile load on the sample, wherein the tensile load is equal to a compression load applied by a material compression mechanics testing machine.
